(19) United States
(12) Patent Application Publication
(10) Pub. No.: US 2018/0053628 A1
(43) Pub. Date: Feb. 22, 2018

(54) Separation Grid for Plasma Chamber

(71) Applicant: Mattson Technology, Inc., Fremont, CA (US)

(72) Inventors: Vijay M. Vaniapura, Tracy, CA (US); Shawming Ma, Sunnyvale, CA (US); Vladimir Nagorny, Tracy, CA (US); Ryan M. Pakulski, Discovery Bay, CA (US)

(21) Appl. No.: 15/591,163

(22) Filed: May 10, 2017

Related U.S. Application Data
(60) Provisional application No. 62/376,594, filed on Aug. 18, 2016.

(51) Int. Cl. H01J 37/32; H01L 21/67

(52) U.S. Cl. CPC H01J 37/3244; H01J 2237/32; H01L 21/67248; H01J 37/32724

(57) ABSTRACT

Separation grids for plasma processing apparatus are provided. In some embodiments, a plasma processing apparatus includes a plasma chamber. The plasma processing apparatus includes a processing chamber. The processing chamber can be separated from the plasma chamber. The apparatus can include a separation grid. The separation grid can separate the plasma chamber and the processing chamber. The apparatus can include a temperature control system. The temperature control system can be configured to regulate the temperature of the separation grid to affect a uniformity of a plasma process on a substrate. In some embodiments, a separation grid can have a varying thickness profile across a cross-section of the separation grid to affect a flow of neutral species through the separation grid.

### PRIORITY CLAIM

The present application claims the benefit of priority of U.S. Provisional Application Ser. No. 62/376,594, titled “Separation Grid for Plasma Chamber,” filed on Aug. 18, 2016, which is incorporated herein by reference.

### FIELD

The present disclosure relates generally to apparatus, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates.

For a photoresist strip (e.g., dry clean) removal process, it can be undesirable to have direct plasma interaction with a substrate. Rather, plasma can be used mainly as an intermediate for modification of a gas composition and creating chemically active radicals for processing the substrates. Accordingly, plasma processing apparatus for photoresist application can include a processing chamber where the substrate is processed that is separated from a plasma chamber where plasma is generated.

In some applications, a grid can be used to separate a processing chamber from a plasma chamber. The grid can be transparent to neutral species but not transparent to charged particles from the plasma. The grid can include a sheet of material with holes. Depending on the process, the grid can be made of a conductive material (e.g., Al, Si, SiC, etc.) or non-conductive material (e.g., quartz, etc.).

Changing grids can be an expensive and long procedure and can require, for instance, opening the processing chamber. Opening the processing chamber can break the vacuum in the processing chamber and can expose the processing chamber to an atmosphere. After the processing chamber has been exposed to the atmosphere, it typically has to be reconditioned again. Reconditioning can require processing many wafers using a plasma until all air contaminants are removed and walls in both the plasma chamber and the processing chamber reach suitable process conditions. In addition, the process flow for processing the wafers may have to be interrupted, leading to expensive downtime.

Because of this difficulty, many manufacturers avoid changing grids by dedicating process chambers to specific processes, each with its own specially tailored separation grid. If a wafer needs to be subjected to a different process, the wafer can be sent to a different processing chamber. This can be inconvenient and can complicate the flow of the manufacturing process. However, it can be preferred to opening the process chamber to change out the separation grid.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus. The plasma processing apparatus can include a plasma chamber and a processing chamber separated from the plasma chamber. The plasma processing apparatus can include a separation grid separating the plasma chamber from the processing chamber. The plasma processing apparatus can further include a temperature control system configured to regulate the temperature of the separation grid to affect the uniformity of a plasma process on a substrate.

Another example aspect of the present disclosure is directed to a plasma processing apparatus. The plasma processing apparatus can include a plasma chamber and a processing chamber separated from the plasma chamber. The plasma processing apparatus can include a separation grid separating the plasma chamber from the processing chamber. The separation grid can have a varying thickness profile across a cross-section of the separation grid to affect the flow of neutral species through the separation grid.

Other example aspects of the present disclosure are directed to systems, methods, devices, and processes for plasma processing a substrate using a plasma processing apparatus.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a separation grid that can be used in a plasma processing apparatus;

FIG. 2 depicts a plasma processing apparatus according to example embodiments of the present disclosure;

FIG. 3 depicts an example separation grid according to example embodiments of the present disclosure;

FIG. 4 depicts an example separation grid according to example embodiments of the present disclosure;

FIG. 5 depicts a plasma processing apparatus according to example embodiments of the present disclosure;

FIG. 6 depicts an example separation grid according to example embodiments of the present disclosure;

FIG. 7 depicts an example separation grid according to example embodiments of the present disclosure;

FIG. 8 depicts an example separation grid according to example embodiments of the present disclosure;

FIG. 9 depicts an example separation grid according to example embodiments of the present disclosure;

FIG. 10 depicts an example separation grid according to example embodiments of the present disclosure;

FIG. 11 depicts an example separation grid according to example embodiments of the present disclosure;

FIG. 12 depicts an example separation grid according to example embodiments of the present disclosure;

FIG. 13 depicts an example separation grid according to example embodiments of the present disclosure;

FIG. 14 depicts an example separation grid according to example embodiments of the present disclosure; and

FIG. 15 depicts an example separation grid according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

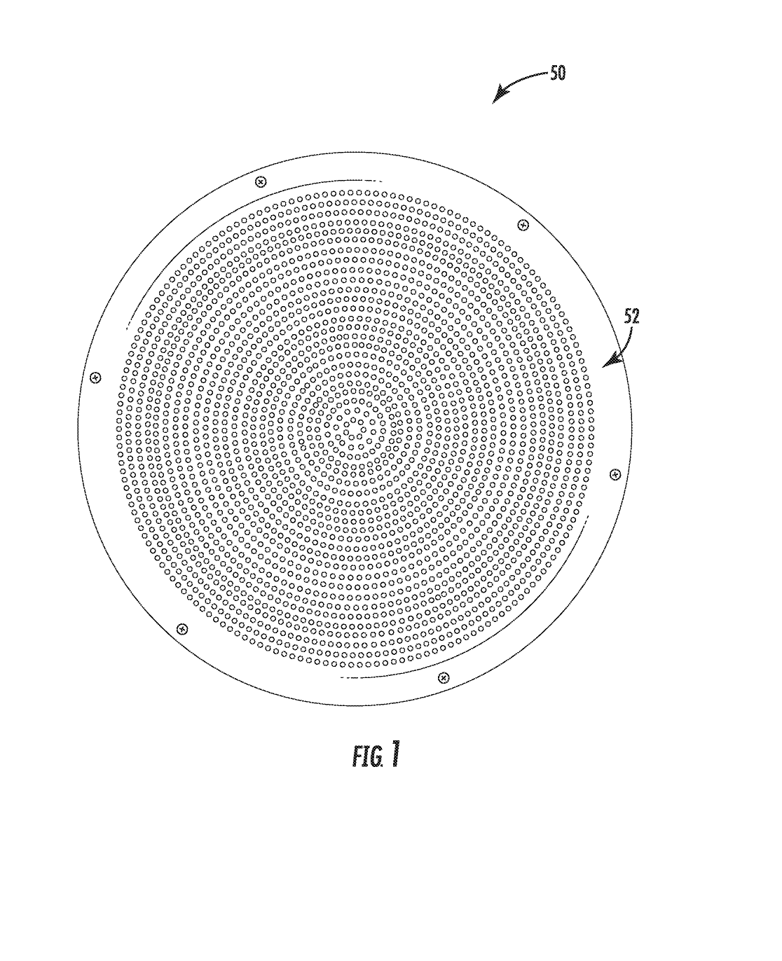

Example aspects of the present disclosure are directed to a separation grid for controlling process profile in a plasma processing apparatus. FIG. 1 depicts an example separation grid 50 used in a plasma processing chamber. As shown, the separation grid 50 can include a sheet of material with holes 52. Charged particles can recombine on the walls and in their path through the holes, while neutral species freely flow through the holes. Some neutral radicals created in plasma may also “die” when colliding with walls, but usually material of the grid is chosen in such a way that the probability of this process (recombination or conversion) for the gas used in plasma is very low. The size of the holes and thickness of the grid may affect transparency for both charged and neutral particles, but much stronger affect charged particles.

In some applications, ultraviolet (UV) radiation coming from the plasma may need to be blocked to reduce damage to features on the substrate. In these applications, a dual grid can be used. The dual grid can include two single grids (e.g., top and bottom) with holes distributed in special patterns on each of them, so that there is no direct line of sight between the plasma chamber and the processing chamber.

An important characteristic of the plasma processing performance can be the uniformity of the process across the substrate (photoresist strip, surface cleaning or modification, etc.). Process profile on the substrate depends on the gas flow, gas pressure and on gas composition. For example, reducing chemistry (H₂/N₂ or any H₂ containing mixtures, but without oxygen), which is used for photoresist with high dose of implants can have a tendency to strongly center-fast process, with any reasonable gas flow and pressure, or construction of the source. This is because highly reactive hydrogen atoms created in plasma have very high mobility and tend to form an “H-rich” gas mixture in the center and “H-poor” gas mixture near the walls. When this gas flows through the grid and react with the substrate, the process rate in the center is much larger that at the edge.

A grid pattern for a separation grid used in a plasma processing chamber can be an effective way of controlling the process profile across a wafer in a plasma process. For instance, to correct a center-fast process profile a separation grid with the hole pattern dense at the edge and rare in the center can be used. On the other hand, oxygen based chemistry used for most of common photoresist films creates more or less flat process profile, so the hole pattern of the separation grid can be almost uniform, or even center-dense.

Other process parameters, (e.g., gas flow, pressure, etc.) can be used mainly for fine tuning of the process profile. Because of that large influence of the process chemistry on the process profile across the wafer, separation grids may be compatible only with the process chemistry for which the separation grid is designed. If a different process needs to be performed, the separation grid of the plasma processing chamber may have to be changed.

According to example aspects of the present disclosure, a separation grid is provided that can allow for control of the neutral species passing through the separation grid during a plasma process without requiring opening of the chamber and changing out of the separation grid. In some embodiments, a temperature of the separation grid can be actively controlled according to a desired temperature profile to control the flow of neutral species through the separation grid. In some embodiments, control of the neutral species can be accomplished through the shape and thickness of the cross-section of the separation grid.

More particularly, the temperature of the separation grid can modulate the wafer process performance, primarily on the photoresist ash rate and the surface oxidation. When the wafer or substrate is placed on the heating block, the temperature of the heating block can dominate the process performance. However, when the substrate is lifted up in a pin-up mode (e.g. supported by pins), the substrate can be much closer to the grid than to the heater block. So the temperature of the grid can affect the process performance. Furthermore, the temperature of the grid can further control the neutral species that can go through the grid, providing another control parameter for the process performance such as uniformity, surface oxidation and ash rate.

According to particular aspects of the present disclosure, the separation grid can include an actively regulated temperature control system to control the temperature of the separation grid according to a desired temperature profile. The temperature profile can be a fixed temperature during a plasma process or can be a variable temperature that varies during the plasma process. In addition to single zone temperature control, the temperature control system can be configured for multi-zone temperature control to compensate the non-uniform plasma heating nature from the source. The multi-zone temperature control system can be configured to regulate the temperature of different zones (e.g., a center zone and a peripheral zone) of the separation grid to achieve a desired temperature profile.

In some embodiments, the temperature control system can include one or more heating elements embedded in the separation grid. The one or more heating elements can be coupled to a power source (e.g., located outside of the plasma processing chamber interior) via one or more conductors. The heating elements can be controlled to regulate the temperature of the separation grid. For instance, a controller can control the electrical current provided to the one or more heating elements to achieve a desired temperature of the separation grid. For instance, when the temperature of the separation grid is below a desired temperature set point, the controller can control a power source to provide or increase electrical current to the heating elements to heat up the separation grid until the desired temperature set point is reached. When the grid temperature is greater than a desired temperature set point, the controller can turn off or reduce the electrical current provided to the heating element to allow the separation grid to cool. In some embodiments, the heating element can act as a heat sink to transfer heat away from the separation grid through, for instance, the one or more conductors.

In some embodiments, the temperature control system can include channels to circulate a fluid (e.g., one or more gases, water, coolant, etc.) through the separation grid to control the temperature of the separation grid. For instance, a cooling fluid can be circulated through the channels in the separation grid to reduce a temperature of the separation grid. A heating fluid can be circulated through the channels in the separation grid to increase a temperature of the separation grid.

In some embodiments, a temperature sensor (e.g. a thermocouple) can be in thermal communication with the separation grid so as to measure a temperature of the separation grid. Signals indicative of the temperature of the separation grid can be provided to a controller, which can control the temperature control system associated with the separation grid to actively regulate the temperature of the separation grid. In this way, the temperature of the separation grid can be controlled as a process parameter to achieve a desired process profile across the substrate during plasma processing.

According to other example aspects of the present disclosure, the separation grid can include varying thickness across a cross-section of the separation grid to further control the process profile. The thickness of the cross-sectional profile can be varied for single grids or for dual grids. For example, the thickness of the cross-sectional profile can be varied to provide a continuously concave shape, a continuously convex shape, a sloped shape, a stepped shape, or other suitable shape.

Aspects of the present disclosure are discussed with reference to a “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within 10% of the stated numerical value.

One example aspect of the present disclosure is directed to a plasma processing apparatus. The plasma processing apparatus includes a plasma chamber. The plasma processing apparatus includes a processing chamber. The processing chamber can be separated from the plasma chamber. The apparatus can include a separation grid. The separation grid can separate the plasma chamber and the processing chamber. The apparatus can include a temperature control system. The temperature control system can be configured to regulate the temperature of the separation grid to affect a uniformity of a plasma process on a substrate.

In some embodiments, the temperature control system can include one or more temperature control units embedded in the separation grid. For instance, the temperature control units can include one or more heating elements. The temperature control system can include one or more controllers. The temperature control system can include one or more temperature sensors. The one or more temperature sensors can be configured to generate a signal indicative of a temperature of the separation grid. The one or more controllers can be configured to control an electrical current provided to the one or more heating elements based at least in part on the signal indicative of the temperature of the separation grid.

In some embodiments, the temperature control units can include one or more first heating elements disposed in a first zone of the separation grid. The temperature control units can include one or more second heating elements disposed in a second zone of the separation grid. The temperature control system can be configured to independently control the one or more first heating elements relative to the one or more second heating elements. The first zone can be a central zone of the separation grid and the second zone can be a peripheral zone of the separation grid.

In some embodiments, the temperature control units can include one or more fluid channels. The temperature control system can include one or more controllers. The temperature control system can include one or more temperature sensors. The temperature sensors can be configured to generate a signal indicative of the temperature of the separation grid. The one or more controllers can be configured to control the flow of fluid provided to the one or more fluid channels based at least in part on the signal indicative of the temperature of the separation grid.

In some embodiments, the temperature control units can include one or more first fluid channels disposed in a first zone of the separation grid. The temperature control units can include one or more second fluid channels disposed in a second zone of the separation grid. The temperature control system can be configured to independent control the flow of fluid through the one or more first fluid channels relative to the one or more second fluid channels. The first zone can be a central zone of the separation grid and the second zone can be a peripheral zone of the separation grid.

Another example aspect of the present disclosure is directed to a separation grid. The separation grid can include a top surface. The separation grid can include a bottom surface. The separation grid can include one or more holes to allow the passage of neutral species. The separation grid can include one or more temperature control units embedded in the separation grid.

In some embodiments, the one or more temperature control units can include one or more heating elements. For instance, the one or more temperature control units can include one or more first heating elements disposed in a first zone of the separation grid. The one or more temperature control units can include one or more second heating elements disposed in a second zone of the separation grid. The first zone can be a central zone of the separation grid and the second zone can be a peripheral zone of the separation grid.

In some embodiments, the one or more temperature control units can include one or more fluid channels. For instance, the one or more temperature control units can include one or more first fluid channels disposed in a first zone of the separation grid. The one or more temperature control units can include one or more second fluid channels disposed in a second zone of the separation grid. The first zone can be a central zone of the separation grid and the second zone can be a peripheral zone of the separation grid.

Another example aspect of the present disclosure is directed to a plasma processing apparatus. The plasma processing apparatus includes a plasma chamber. The plasma processing apparatus includes a processing chamber. The processing chamber can be separated from the plasma chamber. The apparatus can include a separation grid. The separation grid can separate the plasma chamber and the processing chamber. The separation grid can have a varying thickness profile across a cross-section of the separation grid to affect a flow of neutral species through the separation grid.

In some embodiments, the separation grid can have a top surface with a continuously convex profile and a bottom surface with a generally flat profile. In some embodiments, the separation grid can have a top surface with a generally flat profile and a bottom surface with a generally convex profile. In some embodiments, the separation grid can have a top surface with a continuously concave profile and a bottom surface with a generally flat profile. In some embodiments, the separation grid can have a top surface with a generally flat profile and a bottom surface with a continuously concave profile. In some embodiments, the separation grid can have a top surface with sloped peripheral edges and a bottom surface with a generally flat profile. In some embodiments, the separation grid can have a stepped top surface and a bottom surface with a generally flat profile.

In some embodiments, a central portion of the separation grid has a first thickness and a peripheral portion of the separation grid has a second thickness. The first thickness is different from the second thickness. For instance, the first thickness is greater than the second thickness.

In some embodiments, the separation grid is a dual grid. At least one plate of the dual grid has a varying thickness profile across a cross-section of the plate. In some embodiments, the separation grid has a top plate and a bottom plate. The top plate can have a varying thickness profile that mirrors a varying thickness profile of the bottom plate.

Another example aspect of the present disclosure is directed to a separation grid. The separation grid can include a top surface. The separation grid can include a bottom surface. The separation grid can include one or more holes to allow the passage of neutral species. The separation grid can have a varying thickness profile across a cross-section of the separation grid to affect the flow of neutral species through the separation grid.

In some embodiments, the separation grid can have a top surface with a continuously convex profile and a bottom surface with a generally flat profile. In some embodiments, the separation grid can have a top surface with a generally flat profile and a bottom surface with a generally convex profile. In some embodiments, the separation grid can have a top surface with a continuously concave profile and a bottom surface with a generally flat profile. In some embodiments, the separation grid can have a top surface with a generally flat profile and a bottom surface with a continuously concave profile. In some embodiments, the separation grid can have a top surface with sloped peripheral edges and a bottom surface with a generally flat profile. In some embodiments, the separation grid can have a stepped top surface and a bottom surface with a generally flat profile.

In some embodiments, a central portion of the separation grid has a first thickness and a peripheral portion of the separation grid has a second thickness. The first thickness is different from the second thickness. For instance, the first thickness is greater than the second thickness.

In some embodiments, the separation grid is a dual grid. At least one plate of the dual grid has a varying thickness profile across a cross-section of the plate. In some embodiments, the separation grid has a top plate and a bottom plate. The top plate can have a varying thickness profile that mirrors a varying thickness profile of the bottom plate.

Variations and modifications can be made to these example embodiments of the present disclosure.

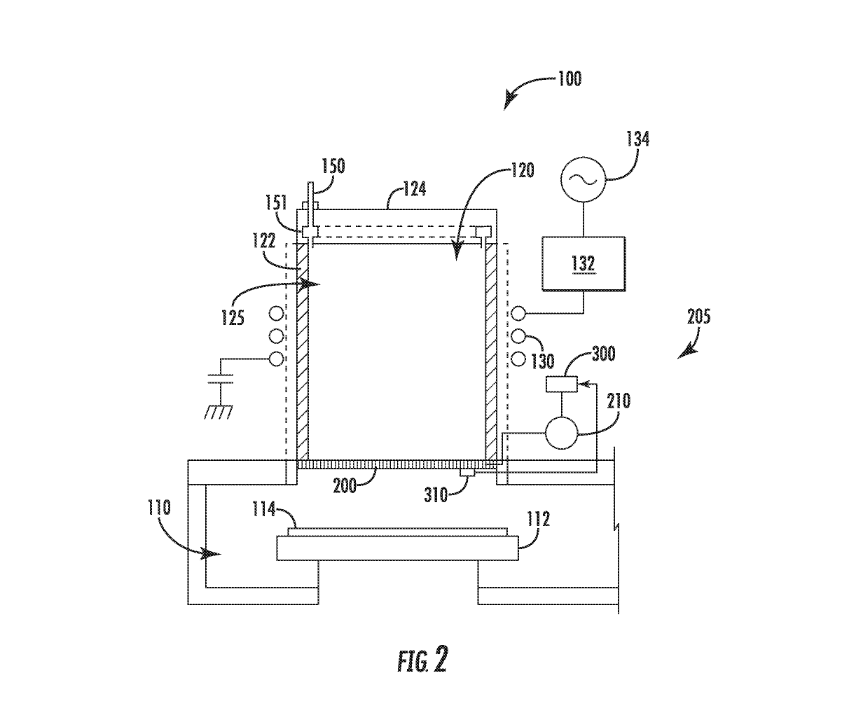

With reference now to the FIGS., example embodiments of the present disclosure will now be discussed in detail. FIG. 2 depicts a plasma processing apparatus according to example embodiments of the present disclosure. As illustrated, plasma processing apparatus 100 includes a processing chamber 110 and a plasma chamber 120 that is separate from the processing chamber 110. Processing chamber 110 includes a substrate holder or pedestal 112 operable to hold a substrate 114 to be processed, such as a semiconductor wafer. In this example illustration, a plasma is generated in plasma chamber 120 (i.e., plasma generation region) by an inductive plasma source and desired particles are channeled from the plasma chamber 120 to the surface of substrate 114 through a separation grid 200 according to example embodiments of the present disclosure. In some embodiments, the separation grid 200 can be grounded.

The plasma chamber 120 includes a dielectric side wall 122 and a ceiling 124. The dielectric side wall 122, ceiling 124, and grid 200 define a plasma chamber interior 125. Dielectric side wall 122 can be formed from any dielectric material, such as quartz. An induction coil 130 is disposed adjacent the dielectric side wall 122 about the plasma chamber 120. The induction coil 130 is coupled to an RF power generator 134 through a suitable matching network 132. Reactant and carrier gases can be provided to the chamber interior from gas supply 150 and annular gas distribution channel 151 or other suitable gas introduction mechanism. When the induction coil 130 is energized with RF power from the RF power generator 134, a plasma is generated in the plasma chamber 120. In a particular embodiment, the plasma reactor 100 can include an optional faraday shield to reduce capacitive coupling of the induction coil 130 to the plasma.

As shown in FIG. 2, the separation grid 200 can include a temperature control system 205 that is configured to regulate or control the temperature of the separation grid 200. The temperature control system 205 can include one or more temperature control units embedded in the separation grid to control the temperature of the separation grid 200. For instance, in the embodiment of FIG. 2, the temperature control system 205 can include a plurality of heating elements embedded in the separation grid 200 to regulate the temperature of the separation grid.

The temperature control system 205 can include or can be coupled to a controller 300. The controller 300 can be any suitable control device that can send control signals to regulate aspects of the temperature control system 205 and/or other aspects of the plasma processing apparatus. In one embodiment, the controller 300 can include one or more processors and one or more memory devices. The one or more processors can execute computer-readable instructions stored in the one or more memory devices to perform the control functions disclosed herein.

In one example, the controller 300 can be configured to send one or more control signals to a power source 210 that is in electrical communication with one or more heating elements in the separation grid 200. The controller 300 can control the power source to provide current to the one or more heating elements in the separation grid 200 based on, for instance, a temperature set point or desired temperature profile for a plasma process.

As shown in FIG. 2, the temperature control system 205 can include at least one temperature sensor 310 (e.g., thermocouple, thermistor, pyrometer, other temperature sensor) in thermal communication with the separation grid 200. Signals from the temperature sensor 310 indicative of a temperature of the separation grid can be provided to the controller 300. The controller 300 can control the power source 210 to provide electrical current to the one or more heating elements based on the signals indicative of the temperature from the temperature sensor 310. As one example, when the temperature of the separation grid is below a desired temperature set point, the controller 300 can control the power source 310 to provide or increase electrical current to the heating elements to heat up the separation grid 200 until the desired temperature set point is reached. When the separation grid temperature is greater than a desired temperature set point, the controller 300 can control the power source 310 to turn off or reduce the electrical current provided to the one or more heating elements to allow the separation grid 200 to cool. In this way, the temperature control system 205 can provide for closed loop control of the temperature of the separation grid 200 according to a programmed temperature profile or set point.

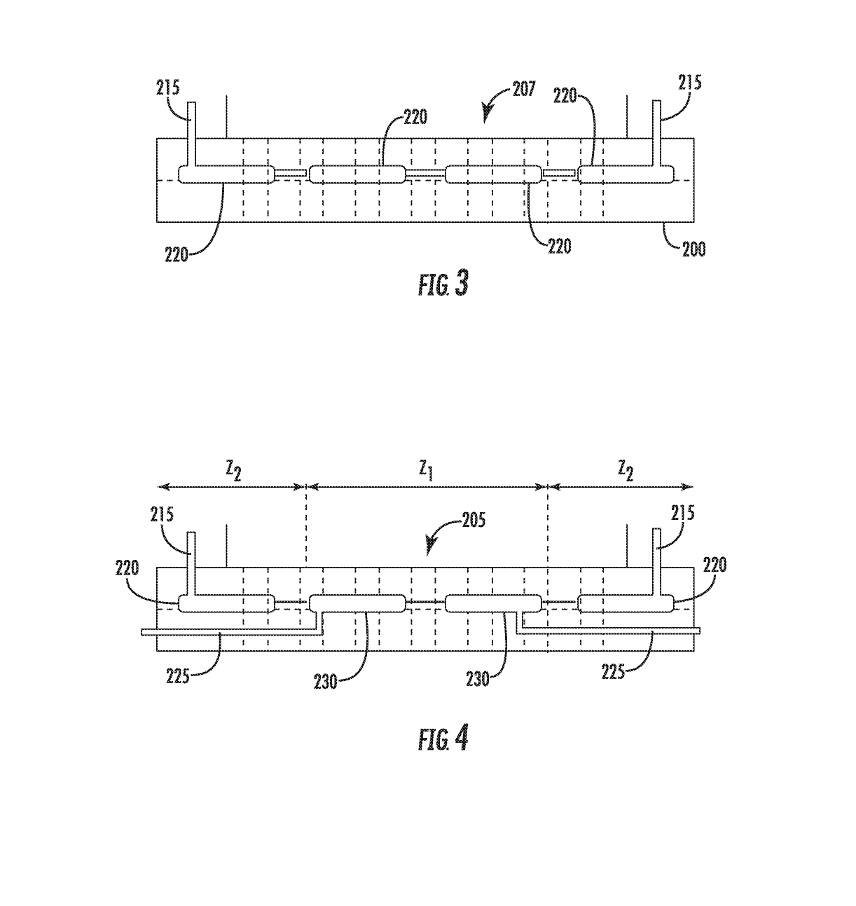

FIG. 3 depicts an example separation grid 200 including one or more heating elements according to example embodiments of the present disclosure. The separation grid 200 can be formed from a conductive material (e.g., Al, Si, SiC, etc.) or non-conductive material (e.g., quartz, etc.). The separation grid 200 can include a plurality of holes 207 to allow the passage of neutral species through the separation grid 200. As shown, the separation grid 200 can include a plurality of heating elements 220. The heating elements 220 can be formed from a conductive material and can be configured to heat up when an electrical current flows through the heating elements 220 from a power source via conductors 215. In some implementations, the heating elements 220 can also act as a heat sink to transfer heat away from the separation grid 200 via conductors 215 during cooling of the separation grid.

In some embodiments, the separation grid 200 can include heating elements disposed in multiple zones to provide for independent temperature control of each of the zones of the separation grid 200. FIG. 4 depicts an example separation grid 200 having one or more heating elements disposed in multiple zones to provide for independent temperature control of each of the zones of the separation grid 200 according to example embodiments of the present disclosure. More particularly, the separation grid 200 includes a first set of heating elements 230 disposed in a central zone Z₁ of the separation grid 200. The first set of heating elements 230 can be coupled to a power source via conductors 225. The separation grid 200 further includes a second set of heating elements 220 disposed in a peripheral zone Z₂ of the separation grid 200. The second set of heating elements 220 can be coupled to a power source via conductors 215.

The present disclosure is discussed with reference to multiple zones including a central zone and a peripheral zone for purposes of illustration and discussion. Those of ordinary skill in the art, using the disclosures provided herein, will understand that the separation grid 200 can be divided into any number of zones in any suitable fashion without deviating from the scope of the present disclosure.

In the multizone embodiment of FIG. 4, the temperature control system 205 can include an independent power source 310 for each zone and/or an independent temperature sensor 310. In this way, the temperature control system 205 can independently control the multiple zones according to a desired temperature profile. For instance, the central zone Z₁ can be controlled to be at a different temperature than the peripheral zone Z₂ to affect the uniformity of the process profile across the substrate.

FIG. 5 depicts a plasma processing apparatus according to another example embodiment of the present disclosure. Similar to FIG. 2, the plasma processing apparatus 100 of FIG. 5 includes a processing chamber 110 and a plasma chamber 120 that is separate from the processing chamber 110. Processing chamber 110 includes a substrate holder or pedestal 112 operable to hold a substrate 114 to be processed, such as a semiconductor wafer. In this example illustration, a plasma is generated in plasma chamber 120 (i.e., plasma generation region) by an inductive plasma source and desired particles are channeled from the plasma chamber 120 to the surface of substrate 114 through a separation grid 200 according to example embodiments of the present disclosure.

The plasma chamber 120 includes a dielectric side wall 122 and a ceiling 124. The dielectric side wall 122, ceiling 124, and grid 200 define a plasma chamber interior 125. Dielectric side wall 122 can be formed from any dielectric material, such as quartz. An induction coil 130 is disposed adjacent the dielectric side wall 122 about the plasma chamber 120. The induction coil 130 is coupled to an RF power generator 134 through a suitable matching network 132. Reactant and carrier gases can be provided to the chamber interior from gas supply 150 and annular gas distribution channel 151 or other suitable gas introduction mechanism. When the induction coil 130 is energized with RF power from the RF power generator 134, a plasma is generated in the plasma chamber 120. In a particular embodiment, the plasma reactor 100 can include an optional faraday shield to reduce capacitive coupling of the induction coil 130 to the plasma.

As shown in FIG. 5, the separation grid 200 can include a temperature control system 205 that is configured to regulate or control the temperature of the separation grid 200. The temperature control system 205 can include one or more temperature control units embedded in the separation grid to control the temperature of the separation grid 200. For instance, in the embodiment of FIG. 2, the temperature control system 205 can include a plurality of fluid channels embedded in the separation grid 200 to regulate the temperature of the separation grid.

More particularly, in one example embodiment, the temperature control system 205 can include or can be coupled to a controller 300. The controller 300 can be any suitable control device that can send control signals to regulate aspects of the temperature control system 205 and/or other aspects of the plasma processing apparatus. In one embodiment, the controller 300 can include one or more processors and one or more memory devices. The one or more processors can execute computer-readable instructions stored in the one or more memory devices to perform the control functions disclosed herein.

In one example, the controller 300 can be configured to send one or more control signals to a control valve 242 that regulates the flow of a fluid (e.g., gas, water, coolant, heated fluid) etc. from a fluid source 240 to one or more channels in the separation grid 200. The controller 300 can control the control valve 242 to provide fluid to the one or more fluid channels in the separation grid 200 based on, for instance, a temperature set point or desired temperature profile for a plasma process.

As shown in FIG. 5, the temperature control system 205 can include at least one temperature sensor 310 (e.g., thermocouple, thermistor, pyrometer, other temperature sensor) in thermal communication with the separation grid 200. Signals from the temperature sensor 310 indicative of a temperature of the separation grid can be provided to the controller 300. The controller 300 can control the control valve 242 to provide fluid to the one or more fluid channels in the separation grid based on the signals indicative of the temperature from the temperature sensor 310. In this way, the temperature control system 205 can provide for closed loop control of the temperature of the separation grid 200 according to a programmed temperature profile or set point.

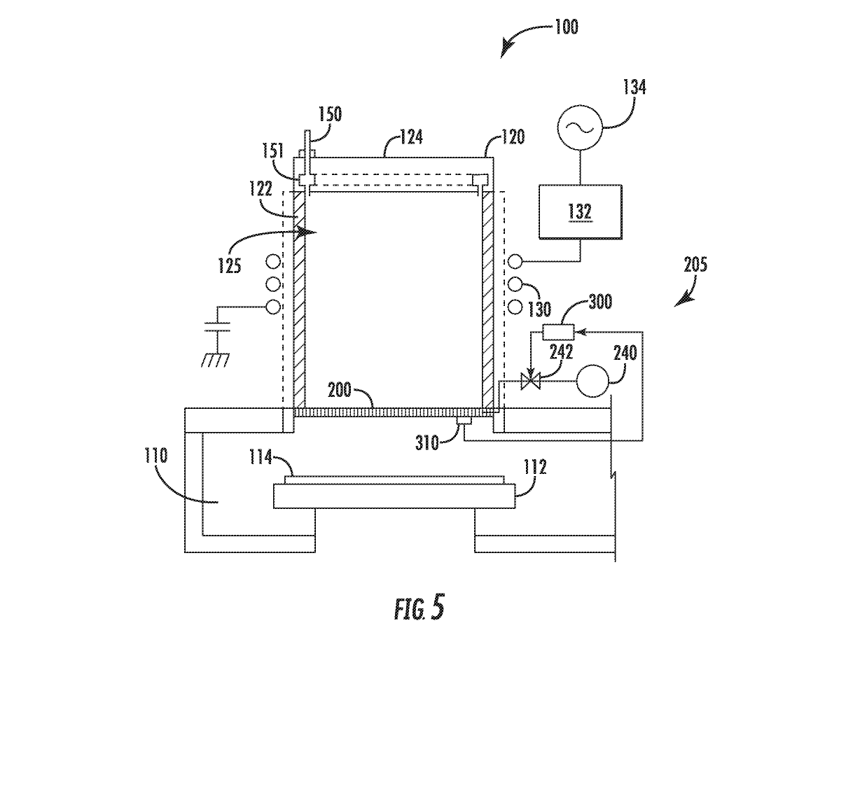

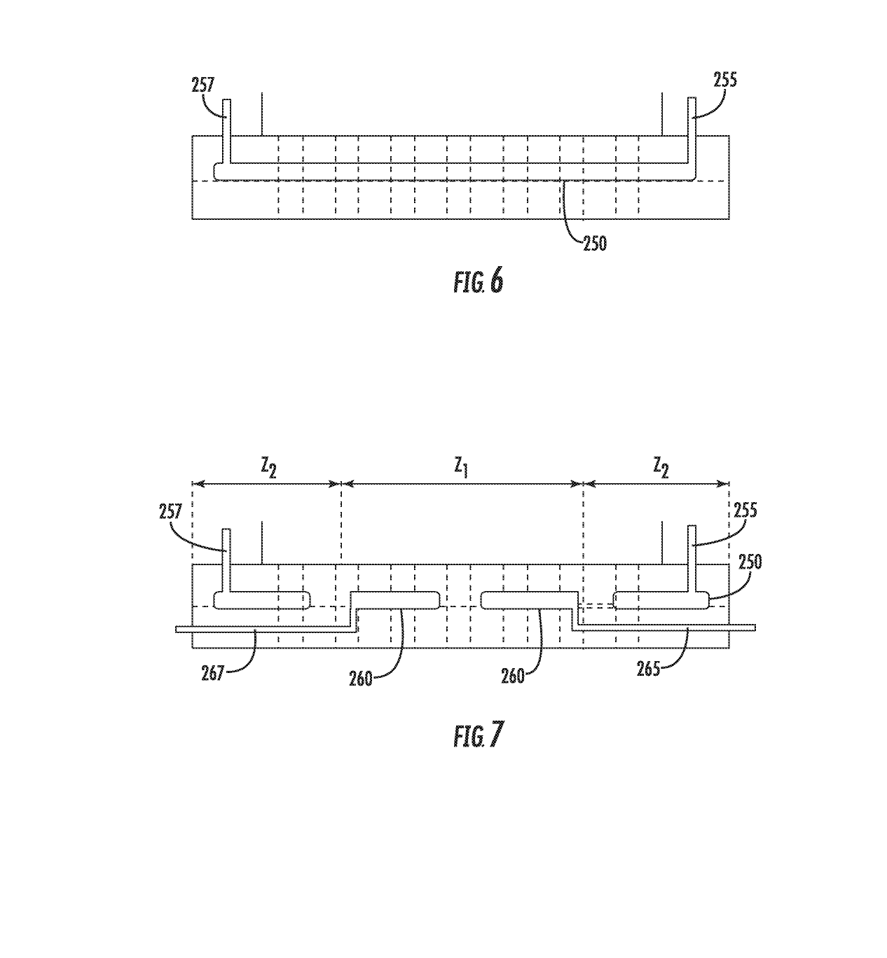

FIG. 6 depicts an example separation grid 200 including one or more fluid channels according to example embodiments of the present disclosure. The separation grid 200 can be formed from a conductive material (e.g., Al, Si, SiC, etc.) or non-conductive material (e.g., quartz, etc.). The separation grid 200 can include a plurality of holes 207 to allow the passage of neutral species through the separation grid 200. As shown, the separation grid 200 can include a fluid channel 250 to allow the passage of a cooling fluid or heating fluid through the separation grid. The fluid channel 250 can receive fluid from a fluid source via inlet 255 and can recirculate fluid back to the fluid source via outlet 257.

In some embodiments, the separation grid 200 can include fluid channels disposed in multiple zones to provide for independent temperature control of each of the zones of the separation grid 200. FIG. 7 depicts an example separation grid 200 having one or more heating elements disposed in multiple zones to provide for independent temperature control of each of the zones of the separation grid 200 according to example embodiments of the present disclosure. More particularly, the separation grid 200 includes a first fluid channel 260 disposed in a central zone Z₁ of the separation grid 200. The fluid channel 260 can receive fluid from a fluid source via inlet 265 and can recirculate fluid back to the fluid source via outlet 267. The separation grid 200 further includes a second fluid channel 250 disposed in a peripheral zone Z₂ of the separation grid 200. The second fluid channel 250 can receive fluid from a fluid source via inlet 255 and can recirculate fluid back to the fluid source via outlet 257.

According to other example embodiments of the present disclosure, the separation grid 200 can have a shape with a varying thickness profile across a cross-section of the separation grid 200 to provide for control of neutral species flowing through the separation grid. Example shapes of separation grids 200 with varying thickness profiles are illustrated in FIGS. 8-15. Other suitable configurations and shapes with varying thickness profiles can be used without deviating from the scope of the present disclosure.

FIG. 8 depicts an example separation grid 200 with a varying thickness profile across a cross-section of the separation grid 200 according to example embodiments of the present disclosure. In the example embodiment of FIG. 8, the separation grid has a top surface 202 with a continuously convex profile and a bottom surface 204 with a generally flat profile. As used herein, “a generally flat profile” with respect to a surface of the separation grid means a surface with no more than a 50 mm difference in height between points on the surface.

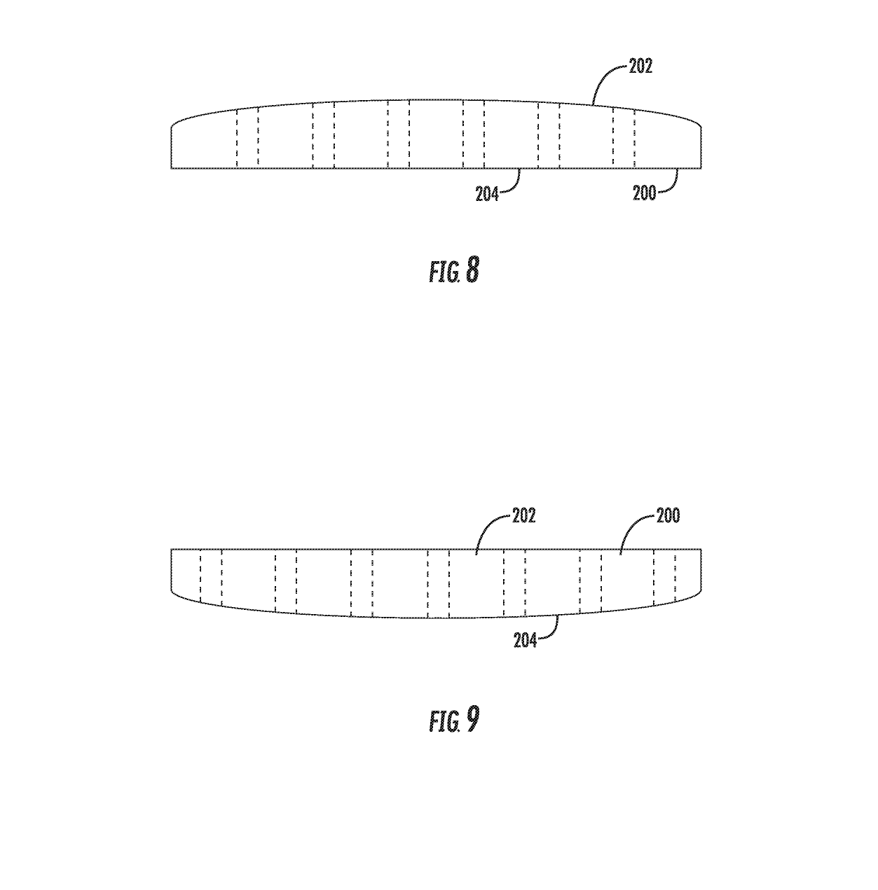

FIG. 9 depicts an example separation grid 200 with a varying thickness profile across a cross-section of the separation grid 200 according to example embodiments of the present disclosure. In the example embodiment of FIG. 9, the separation grid has a top surface 202 with a generally flat profile and a bottom surface 204 with a continuously convex profile.

FIG. 10 depicts an example separation grid 200 with a varying thickness profile across a cross-section of the separation grid 200 according to example embodiments of the present disclosure. In the example embodiment of FIG. 10, the separation grid has a top surface 202 with a continuously concave profile and a bottom surface 204 with a generally flat profile.

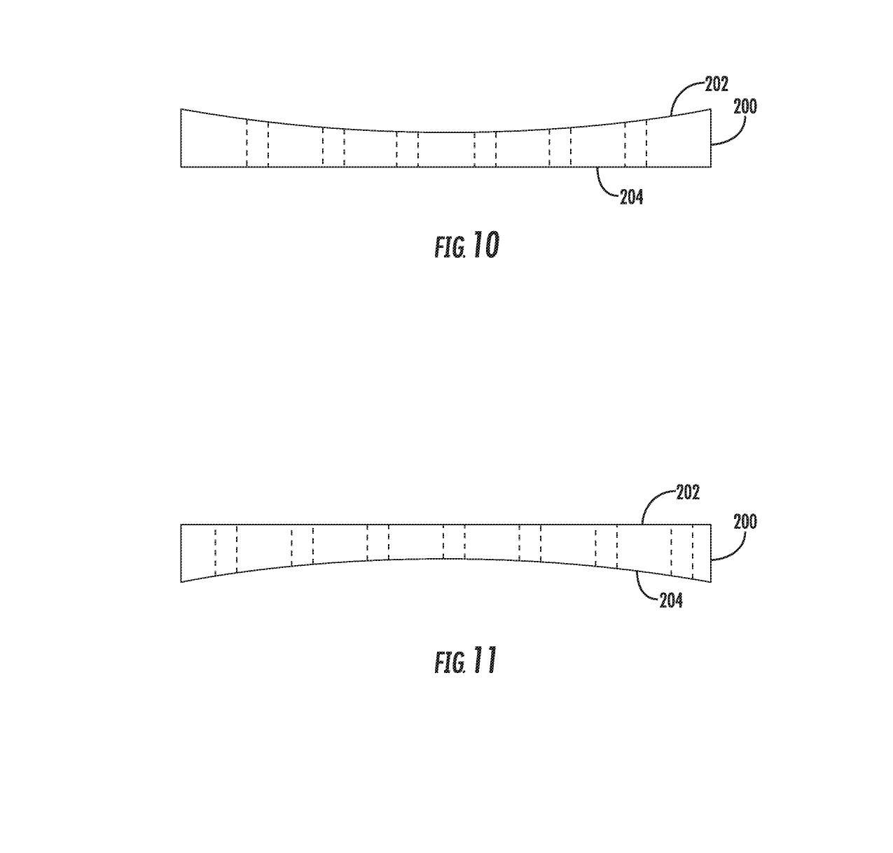

FIG. 11 depicts an example separation grid 200 with a varying thickness profile across a cross-section of the separation grid 200 according to example embodiments of the present disclosure. In the example embodiment of FIG. 9, the separation grid has a top surface 202 with a generally flat profile and a bottom surface 204 with a continuously concave profile.

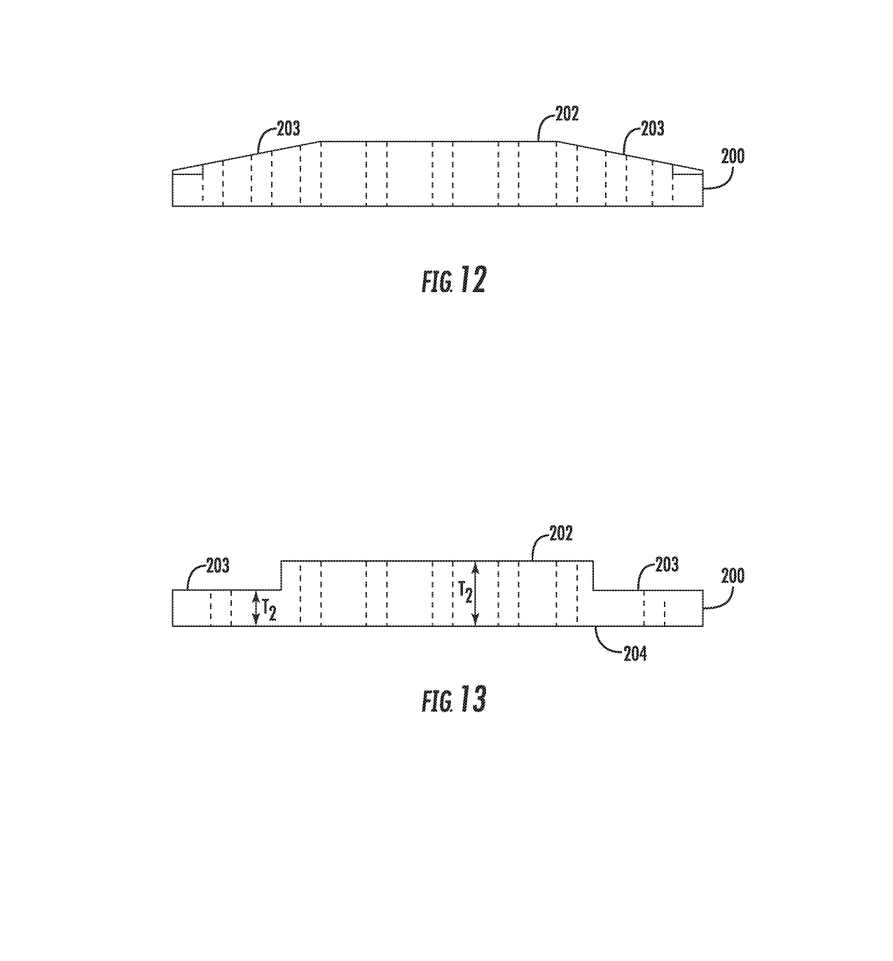

FIG. 12 depicts an example separation grid 200 with a varying thickness profile across a cross-section of the separation grid 200 according to example embodiments of the present disclosure. In the example embodiment of FIG. 8, the separation grid has a top surface 202 with sloped peripheral edges 203 and a bottom surface 204 with a generally flat profile.

FIG. 13 depicts an example separation grid 200 with a varying thickness profile across a cross-section of the separation grid 200 according to example embodiments of the present disclosure. In the example embodiment of FIG. 9, the separation grid has a stepped top surface 202 and a bottom surface 204 with a generally flat profile. More particularly, a central portion 201 of the separation grid 200 has a first thickness T₁. A peripheral portion 203 of the separation grid has a second thickness T₂. The first thickness T₁ is different from the second thickness T₂. For instance, the first thickness T₁ is greater than the second thickness T₂

The above example embodiments have been discussed with reference to a single grid for purposes of illustration. Those of ordinary skill in the art, using the disclosures provided herein, will understand that example aspects of the present disclosure can also be implemented with a dual grid or other multi-plate separation grid.

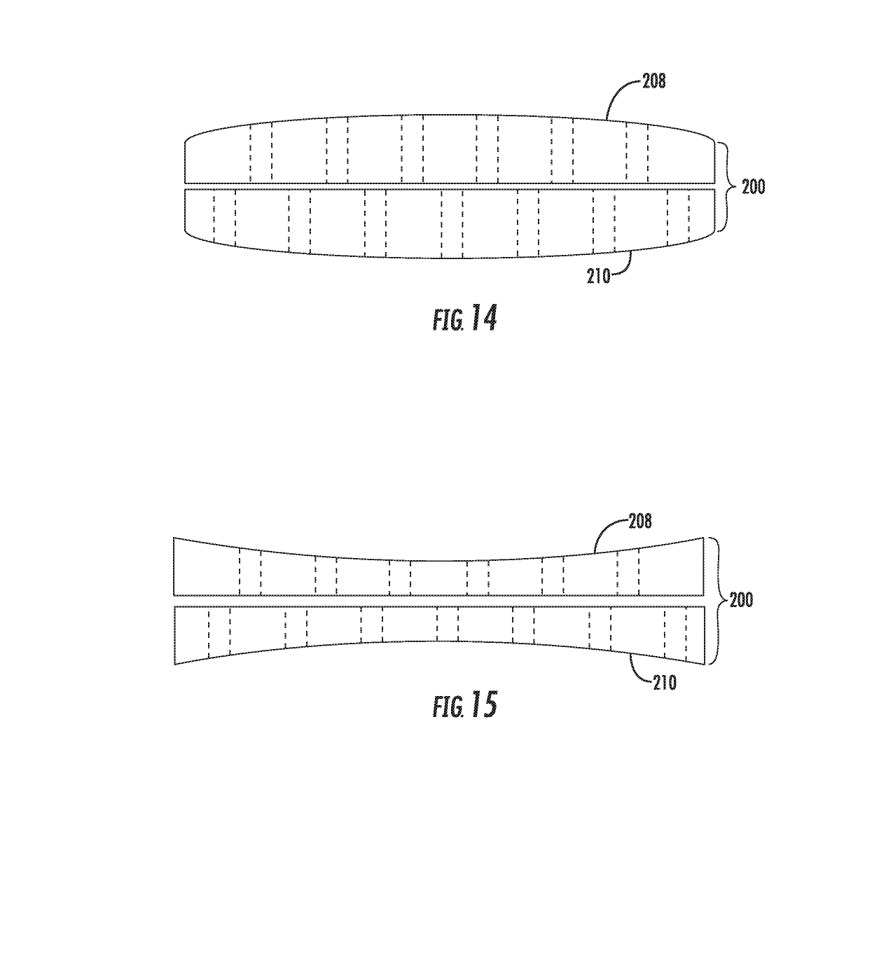

For instance, FIG. 14 depicts an example dual separation grid 200 with a varying thickness profile across a cross-section of the separation grid 200 according to example embodiments of the present disclosure. In the example embodiment of FIG. 14, the separation grid 200 has a top plate 208 with continuously convex top surface and a bottom plate 209 with a continuously convex bottom surface. In this way, the top plate 208 has a shape that mirrors the bottom plate 209.

FIG. 15 depicts an example dual separation grid 200 with a varying thickness profile across a cross-section of the separation grid 200 according to example embodiments of the present disclosure. In the example embodiment of FIG. 14, the separation grid 200 has a top plate 208 with continuously concave top surface and a bottom plate 209 with a continuously concave bottom surface. In this way, the top plate 208 has a shape that mirrors the bottom plate 209.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a plasma chamber;
a processing chamber separated from the plasma chamber;
a separation grid separating the plasma chamber and the processing chamber;
a temperature control system configured to regulate the temperature of the separation grid to affect the uniformity of a plasma process on a substrate.

2. The plasma processing apparatus of claim 1, wherein the temperature control system comprises one or more temperature control units embedded in the separation grid.

3. The plasma processing apparatus of claim 2, wherein the temperature control units comprise one or more heating elements.

4. The plasma processing apparatus of claim 3, wherein the temperature control system comprises:
one or more controllers; and
one or more temperature sensors configured to generate a signal indicative of a temperature of the separation grid;
wherein the one or more controllers are configured to control an electrical current provided to the one or more heating elements based at least in part on the signal indicative of the temperature of the separation grid.

5. The plasma processing apparatus of claim 2, wherein the temperature control units comprise:
one or more first heating elements disposed in a first zone of the separation grid;
one or more second heating elements disposed in a second zone of the separation grid.

6. The plasma processing apparatus of claim 5, wherein the temperature control system is configured to independently control the one or more first heating elements relative to the one or more second heating elements.

7. The plasma processing apparatus of claim 2, wherein the temperature control units comprise one or more fluid channels.

8. The plasma processing apparatus of claim 7, wherein the temperature control system comprises:
one or more controllers; and
one or more temperature sensors configured to generate a signal indicative of a temperature of the separation grid;
wherein the one or more controllers are configured to control the flow of fluid provided to the one or more fluid channels based at least in part on the signal indicative of the temperature of the separation grid.

9. The plasma processing apparatus of claim 8, wherein the temperature control units comprise:
one or more first fluid channels disposed in a first zone of the separation grid;
one or more second fluid channels disposed in a second zone of the separation grid.

10. The plasma processing apparatus of claim 9, wherein the temperature control system is configured to independently control the flow of fluid through the one or more first fluid channels relative to the one or more second fluid channels.

11. A separation grid for a plasma processing apparatus, the separation grid comprising:
a top surface;
a bottom surface;
one or more holes to allow the passage of neutral species; and
one or more temperature control units embedded in the separation grid.

12. The separation grid of claim 11, wherein the one or more temperature control units comprise one or more heating elements.

13. The separation grid of claim 12, wherein the temperature control units comprise:
one or more first heating elements disposed in a first zone of the separation grid;
one or more second heating elements disposed in a second zone of the separation grid.

14. The separation grid of claim 11, wherein the one or more temperature control units comprise one or more fluid channels.

15. The separation grid of claim 14, wherein the temperature control units comprise:
one or more first fluid channels disposed in a first zone of the separation grid;
one or more second fluid channels disposed in a second zone of the separation grid.

16. A separation grid for separating a plasma chamber from a processing chamber in a plasma processing apparatus, the separation grid comprising:
a top surface;
a bottom surface; and
one or more holes to allow the passage of neutral species;
wherein the separation grid has a varying thickness profile across a cross-section of the separation grid to affect a flow of neutral species through the separation grid.

17. The separation grid of acclaim 16, wherein the separation grid has a top surface with a continuously convex profile or a continuously concave profile and a bottom surface with a generally flat profile.

18. The separation grid of claim 16, wherein the separation grid has a top surface with a generally flat profile and a bottom surface with a generally convex profile or a continuously concave profile.

19. The separation grid of claim 16, wherein the separation grid has a top surface with sloped peripheral edges and a bottom surface with a generally flat profile.

20. The separation grid of claim 16, wherein the separation grid has a stepped top surface and a bottom surface with a generally flat profile.

21. The separation grid of claim 16, wherein a central portion of the separation grid has a first thickness and a peripheral portion the separation grid has a second thickness, the first thickness being different from the second thickness.

22. The separation grid of claim 21, wherein the first thickness is greater than the second thickness.

23. The separation grid of claim 16, wherein the separation grid is a dual grid, at least one plate of the dual grid having a varying thickness profile across a cross-section of the plate.

24. The separation grid of claim 23, wherein the separation grid comprises a top plate and a bottom plate, the top plate having a varying thickness profile that mirrors a varying thickness profile of the bottom plate.
